(19) United States
(12) Patent Application Publication
(10) Pub. No.: US 2026/0107380 A1
(43) Pub. Date: Apr. 16, 2026

(54) INTERCONNECT SUBSTRATE AND METHOD OF MAKING THE SAME

(71) Applicant: SHINKO ELECTRIC INDUSTRIES CO., LTD., Nagano (JP)

(72) Inventor: Keigo SATO, Nagano (JP)

(21) Appl. No.: 19/355,397

(22) Filed: Oct. 10, 2025

(30) Foreign Application Priority Data
Oct. 16, 2024 (JP) 2024-180974

(51) Int. Cl. H05K 1/03; H01L 23/00; H05K 3/00

(52) U.S. Cl. CPC H05K 1/0306; H05K 3/0029; H05K 2201/0195; H05K 2201/09154; H10W 74/15; H10W 90/724; H10W 90/734

(57) ABSTRACT

An interconnect substrate includes a core layer made of glass having one surface and another surface, a first laminate including one or more interconnect layers and one or more insulating layers disposed on the one surface of the core layer, and a first resin portion, wherein a first peripheral portion of the one surface of the core layer is not covered with the first laminate, and wherein the first resin portion covers the first peripheral portion and a side surface of the first laminate.

### CROSS-REFERENCE TO RELATED APPLICATIONS

The present application is based on and claims priority to Japanese Patent Application No. 2024-180974 filed on Oct. 16, 2024, with the Japanese Patent Office, the entire contents of which are incorporated herein by reference.

### FIELD

The disclosures herein generally relate to interconnect substrates and methods of making an interconnect substrate.

### BACKGROUND

As known in the art, interconnect substrates may have core layers and laminates including interconnect layers and insulating layers alternately laminated on the core layers (Patent Document 1). The manufacturing process of such an interconnect substrate may include, for example, preparing a core layer having a plurality of interconnect regions for singulation into interconnect substrates and a cutting region along which cuts are to be made for singulation, and forming a laminate on the upper surface of the core layer. Thereafter, the laminate and the core layer are cut along the cutting region to produce singulated interconnect substrates.

A core layer made of glass may sometimes be used in an interconnect substrate. In this case, there is a possibility that the peripheral portion of the core layer made of glass has structural defects, such as chips or cracks, after the cutting for singulation.

There may be a need to reduce the breakage of the peripheral portion of a core layer in an interconnect substrate having a core layer made of glass.

### RELATED-ART DOCUMENT

### Patent Document

0003

[Patent Document 1] Japanese Laid-Open Patent Publication No. 2014-22465

### SUMMARY

According to an aspect of the embodiment, an interconnect substrate includes a core layer made of glass having one surface and another surface, a first laminate including one or more interconnect layers and one or more insulating layers disposed on the one surface of the core layer, and a first resin portion, wherein a first peripheral portion of the one surface of the core layer is not covered with the first laminate, and wherein the first resin portion covers the first peripheral portion and a side surface of the first laminate.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIGS. 1A and 1B are drawings illustrating an example of an interconnect substrate according to the first embodiment;

FIG. 2 is a drawing illustrating an example of a manufacturing process of the interconnect substrate according to the first embodiment;

FIGS. 3A through 3D are drawings illustrating the example of the manufacturing process of the interconnect substrate according to the first embodiment;

FIGS. 4A through 4C are drawings illustrating the example of the manufacturing process of the interconnect substrate according to the first embodiment;

FIG. 5 is a cross-sectional view illustrating an example of an interconnect substrate according to a variation of the first embodiment; and

FIG. 6 is a cross-sectional view illustrating an example of a semiconductor device according to the second embodiment.

### DESCRIPTION OF EMBODIMENTS

Embodiments of the invention will be described below with reference to the accompanying drawings. In these drawings, the same components are denoted by the same reference numerals, and duplicate descriptions may be omitted.

### First Embodiment

### Structure of Interconnect Substrate of First Embodiment

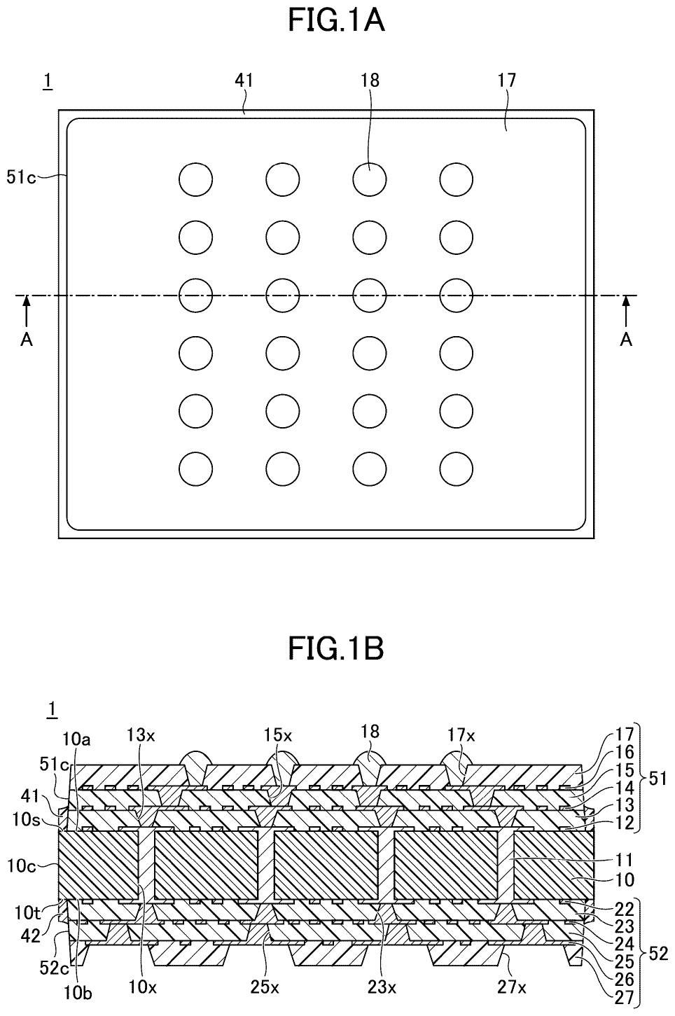

FIGS. 1A and 1B are drawings illustrating an example of an interconnect substrate according to a first embodiment. FIG. 1A is a plan view and FIG. 1B is a cross-sectional view taken along the line A-A in FIG. 1A.

Referring to FIG. 1, an interconnect substrate 1 includes a core layer 10 having a first surface 10a and a second surface 10b opposite the first surface 10a, a first laminate 51 including interconnect layers and insulating layers alternately laminated on the first surface 10a of the core layer 10, a second laminate 52 including interconnect layers and insulating layers alternately laminated on the second surface 10b of the core layer 10, a first resin portion 41, and a second resin portion 42. The interconnect substrate 1 may include external connection terminals 18.

The first laminate 51 includes an interconnect layer 12, an insulating layer 13, an interconnect layer 14, an insulating layer 15, an interconnect layer 16, and a solder resist layer 17 sequentially laminated on the first surface 10a of the core layer 10. The second laminate 52 includes an interconnect layer 22, an insulating layer 23, an interconnect layer 24, an insulating layer 25, an interconnect layer 26, and a solder resist layer 27 sequentially laminated on the second surface 10b of the core layer 10.

In the first embodiment, for convenience, the solder resist layer 17 side of the interconnect substrate 1 is referred to as an upper side or a first side, and the solder resist layer 27 side is referred to as a lower side or a second side. The surface of a portion oriented in the same direction as the solder resist layer 17 side is referred to as a first surface or an upper surface, and the surface of the portion oriented in the same direction as the solder resist layer 27 side is referred to as a second surface or a lower surface. However, the interconnect substrate 1 may be positioned upside down when used, or may be arranged at any angle. The plan view refers to the view of an object as seen from the direction normal to the first surface 10a of the core layer 10, and the plan shape refers to the shape of an object as seen from the direction normal to the first surface 10a of the core layer 10.

The core layer 10 is made of glass. Although the kind of glass constituting the core layer 10 is not limited, alkali-free glass, quartz glass, borosilicate glass, or the like may be used, for example. The thickness of the core layer 10 is, for example, in the range of approximately 100 to 1000 μm. The core layer 10 has through holes 10x that extend through the core layer 10 in the thickness direction. The plan shape of each of the through holes 10x is, for example, circular. The diameter of each of the through holes 10x may be, for example, from 100 μm to 500 μm.

A first peripheral portion 10s of the first surface 10a of the core layer 10 is not covered with the first laminate 51. The first peripheral portion 10s is positioned on the outer side of the first laminate 51 in plan view and has a closed-loop shape. The width of the first peripheral portion 10s may be, for example, from 50 μm to 300 μm.

A side surface 51c of the first laminate 51 is constituted by the side surface of the insulating layer 13, the side surface of the insulating layer 15, and the side surface of the solder resist layer 17. The side surface 51c of the first laminate 51 is inclined inward toward the solder resist layer 17, in the direction away from the side surface 10c of the core layer 10, in cross-sectional view, for example. Alternatively, the side surface 51c of the first laminate 51 may be perpendicular to the first surface 10a of the core layer 10.

The first resin portion 41 covers the first peripheral portion 10s and a portion of the side surface 51c of the first laminate 51 located toward the first peripheral portion 10s. In the illustrated example, the upper surface of the first resin portion 41 has a region in which the height from the first surface 10a of the core layer 10 decreases with the distance from the side surface 51c of the first laminate 51 toward the side surface 10c of the core layer 10. The height of the upper surface of the first resin portion 41 from the first surface 10a of the core layer 10 becomes the lowest, for example, at the position directly above the side surface 10c of the core layer 10.

The thickness of the thinnest portion of the first resin portion 41 in the stacking direction of the first laminate 51 may be, for example, from 10 μm to 50 μm. The thickness of the thickest portion of the first resin portion 41 in the stacking direction of the first laminate 51 may be, for example, from 50 μm to 250 μm. The material of the first resin portion 41 may be, for example, an insulating resin mainly composed of an epoxy-based resin or a polyimide-based resin.

A second peripheral portion 10t of the second surface 10b of the core layer 10 is not covered with the second laminate 52. The second peripheral portion 10t is positioned on the outer side of the second laminate 52 in plan view and has a closed-loop shape. The width of the second peripheral portion 10t may be, for example, from 50 μm to 300 μm.

A side surface 52c of the second laminate 52 is constituted by the side surface of the insulating layer 23, the side surface of the insulating layer 25, and the side surface of the solder resist layer 27. The side surface 52c of the second laminate 52 is inclined inward toward the solder resist layer 27, in the direction away from the side surface 10c of the core layer 10, in cross-sectional view, for example. Alternatively, the side surface 52c of the second laminate 52 may be perpendicular to the second surface 10b of the core layer 10.

The second resin portion 42 covers the second peripheral portion 10t and a portion of the side surface 52c of the second laminate 52 located toward the second peripheral portion 10t . In the illustrated example, the lower surface of the second resin portion 42 has a region in which the vertical distance from the second surface 10b of the core layer 10 decreases with the horizontal distance from the side surface 52c of the second laminate 52 toward the side surface 10c of the core layer 10. The vertical distance of the lower surface of the second resin portion 42 from the second surface 10b of the core layer 10 becomes the shortest, for example, at the position directly below the side surface 10c of the core layer 10.

The thickness of the thinnest portion of the second resin portion 42 in the stacking direction of the second laminate 52 may be, for example, from 10 μm to 50 μm. The thickness of the thickest portion of the second resin portion 42 in the stacking direction of the second laminate 52 may be, for example, from 50 μm to 250 μm. The material of the second resin portion 42 may be, for example, an insulating resin mainly composed of an epoxy-based resin or a polyimide-based resin.

The interconnect layer 12 is disposed on the first surface 10a of the core layer 10. The interconnect layer 22 is disposed on the second surface 10b of the core layer 10. The interconnect layer 12 and the interconnect layer 22 are electrically connected by through interconnects 11 formed in the through holes 10x. Each of the interconnect layers 12 and 22 is patterned in a predetermined plan shape. Copper (Cu) or the like, for example, may be used as a material for the interconnect layers 12 and 22 and the through interconnects 11. The thicknesses of the interconnect layers 12 and 22 are, for example, in the range of approximately 10 to 40 μm. The interconnect layer 12, the interconnect layer 22, and the through interconnects 11 may be seamlessly formed.

The insulating layer 13 is an interlayer insulating layer disposed on the first surface 10a of the core layer 10 and covering the interconnect layer 12. The material of the insulating layer 13 may be, for example, an insulating resin mainly composed of an epoxy-based resin or a polyimide-based resin. The thickness of the insulating layer 13 may be, for example, in the range of approximately 30 to 40 μm. The insulating layer 13 may contain a filler such as silica (SiO2).

Via holes 13x are formed in the insulating layer 13 to extend through the insulating layer 13 and reach the upper surface of the interconnect layer 12. The via holes 13x may each be an inverted truncated conical hole for which the diameter of the opening toward the insulating layer 15 is larger than the diameter of the opening at the upper surface of the interconnect layer 12.

The interconnect layer 14 is formed on the first side of the insulating layer 13. The interconnect layer 14 includes via interconnects filling the via holes 13x and an interconnect pattern formed on the upper surface of the insulating layer 13. The interconnect pattern is electrically connected to the interconnect layer 12 via the via interconnects. The material of the interconnect layer 14 and the thickness of the interconnect pattern may be substantially the same as those of the interconnect layer 12, for example.

The insulating layer 15 is formed on the upper surface of the insulating layer 13 so as to cover the interconnect layer 14. The material and the thickness of the insulating layer 15 may be the same as those of the insulating layer 13, for example. The insulating layer 15 may contain a filler such as silica (SiO₂).

Via holes 15x are formed in the insulating layer 15 to extend through the insulating layer 15 and reach the upper surface of the interconnect layer 14. The via holes 15x may each be an inverted truncated conical hole for which the diameter of the opening toward the solder resist layer 17 is larger than the diameter of the opening at the upper surface of the interconnect layer 14.

The interconnect layer 16 is formed on the first side of the insulating layer 15. The interconnect layer 16 includes via interconnects filling the via holes 15x and pads formed on the upper surface of the insulating layer 15. The pads are electrically connected to the interconnect layer 14 via the via interconnects. The material of the interconnect layer 16 and the thickness of the pads may be substantially the same as those of the interconnect layer 12, for example. The thickness of the pads may be larger than that of the interconnect layer 12. The interconnect layer 16 may also include an interconnect pattern in addition to the pads.

The solder resist layer 17 is a protective insulating layer located as the outermost layer on the first side of the interconnect substrate 1, and is formed on the upper surface of the insulating layer 15 so as to cover the interconnect layer 16. The solder resist layer 17 has openings 17x, and portions of the upper surface of the interconnect layer 16 are located within the openings 17x. The plan shape of each of the openings 17x may be, for example, circular. The interconnect layer 16 situated in the openings 17x may be used as pads for electrical connections with an electronic component such as a semiconductor chip, for example. The solder resist layer 17 may be formed of, for example, a photosensitive epoxy-based insulating resin or acrylic-based insulating resin. The thickness of the solder resist layer 17 is, for example, in the range of approximately 15 to 35 μm.

On the surface of the interconnect layer 16 exposed in the openings 17x, a metal layer may be formed, or an organic coating may be formed by applying an antioxidant treatment such as organic solderability preservative (OSP) treatment. Examples of the metal layer include an Au layer, a Ni/Au layer (a metal layer formed by laminating a Ni layer and an Au layer in this order), a Ni/Pd/Au layer (a metal layer formed by laminating a Ni layer, a Pd layer, and an Au layer in this order), and a Sn layer.

According to need, the external connection terminals 18 may be provided on the interconnect layer 16 exposed in the openings 17x. The external connection terminals 18 are, for example, solder bumps. The material of the solder bumps may be, for example, an alloy containing Pb, an alloy of Sn and Cu, an alloy of Sn and Ag, an alloy of Sn, Ag and Cu, or the like.

The insulating layer 23 is an interlayer insulating layer disposed on the second surface 10b of the core layer 10 and covering the interconnect layer 22. The material and the thickness of the insulating layer 23 may be substantially the same as those of the insulating layer 13, for example. The insulating layer 23 may contain a filler such as silica (SiO2).

Via holes 23x are formed in the insulating layer 23 to extend through the insulating layer 23 and reach the lower surface of the interconnect layer 22. The via holes 23x may each be a truncated conical hole for which the diameter of the opening toward the insulating layer 25 is larger than the diameter of the opening at the lower surface of the interconnect layer 22.

The interconnect layer 24 is formed on the second side of the insulating layer 23. The interconnect layer 24 includes via interconnects filling the via holes 23x and an interconnect pattern formed on the lower surface of the insulating layer 23. The interconnect pattern is electrically connected to the interconnect layer 22 via the via interconnects. The material and thickness of the interconnect layer 24 may be substantially the same as those of the interconnect layer 12, for example.

The insulating layer 25 is formed so as to cover the interconnect layer 24 on the lower surface of the insulating layer 23. The material and thickness of the insulating layer 25 may be substantially the same as those of the insulating layer 13, for example. The insulating layer 25 may contain a filler such as silica (SiO₂).

Via holes 25x are formed in the insulating layer 25 to extend through the insulating layer 25 and reach the lower surface of the interconnect layer 24. The via holes 25x may each be a truncated conical hole for which the diameter of the opening toward the solder resist layer 27 is larger than the diameter of the opening at the lower surface of the interconnect layer 24.

The interconnect layer 26 is formed on the second side of the insulating layer 25. The interconnect layer 26 includes via interconnects filling the via holes 25x and an interconnect pattern formed on the lower surface of the insulating layer 25. The interconnect pattern is electrically connected to the interconnect layer 24 through the via interconnects. The material and the thickness of the interconnect layer 26 may be substantially the same as those of the interconnect layer 12, for example.

The solder resist layer 27 is a protective insulating layer located as the outermost layer on the second side of the interconnect substrate 1, and is formed on the lower surface of the insulating layer 25 to cover the interconnect layer 26. The material and the thickness of the solder resist layer 27 may be substantially the same as those of the solder resist layer 17, for example. The solder resist layer 27 has openings 27x, and portions of the lower surface of the interconnect layer 26 are exposed within the openings 27x. The plan shape of each of the openings 27x may be, for example, circular. The interconnect layer 26 exposed in the openings 27x may be used as pads for electrical connections to a mounting substrate such as a motherboard. If necessary, a metal layer of the kind previously described may be formed on the lower surface of the interconnect layer 26 exposed in the openings 27x, or an oxidation prevention treatment such as OSP treatment may be applied.

### Method of Making Interconnect Substrate

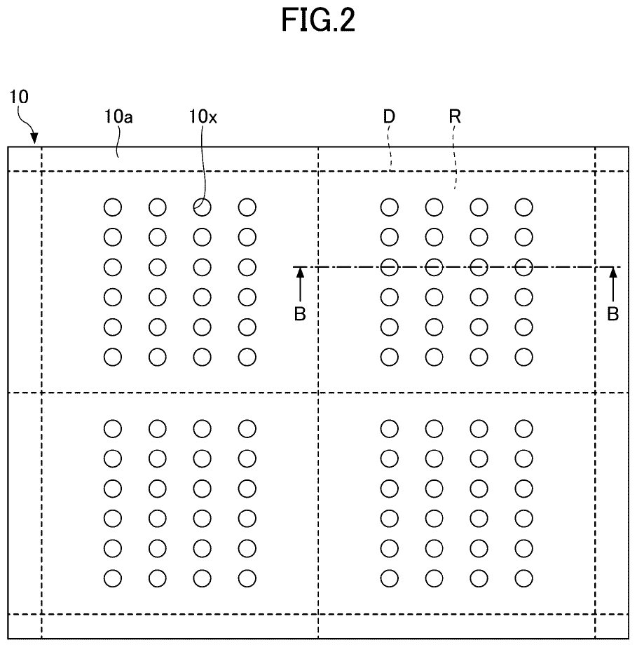

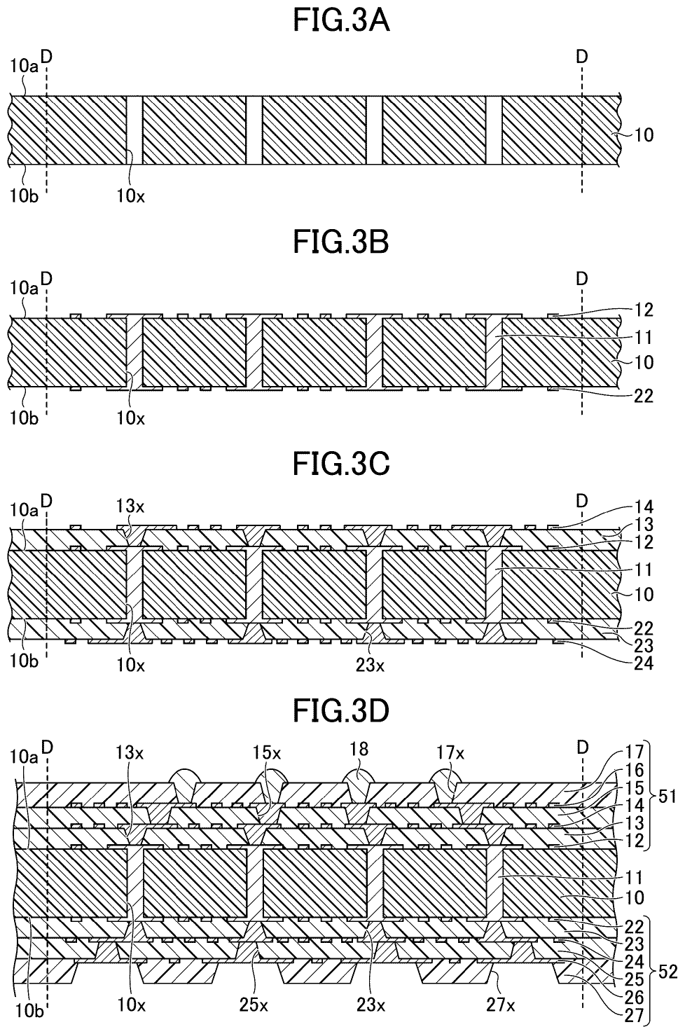

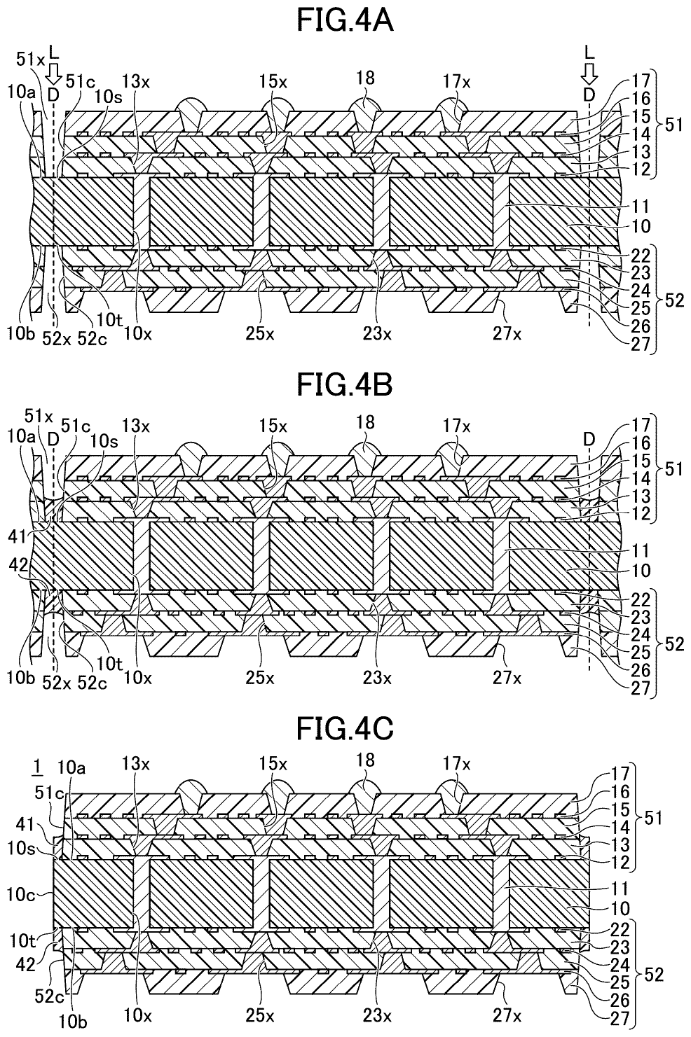

FIG. 2 through FIGS. 4A to 4C are drawings illustrating an example of a manufacturing process of the interconnect substrate according to the first embodiment. FIG. 2 is a plan view, and FIGS. 3A to 3D and FIGS. 4A to 4C are partial cross-sectional views corresponding to the position of the line B-B in FIG. 2.

First, in the step illustrated in FIGS. 2 and 3A, a core layer 10 made of glass is prepared. The core layer 10 includes a plurality of interconnect regions R for singulation into interconnect substrates, and cutting regions D along which cuts are to be made for singulation. Although the cutting regions D are illustrated by lines in FIGS. 2 and 3A, they may each be a region having a constant width. Next, through holes 10x extending from the first surface 10a to the second surface 10b are formed in the core layer 10 inside each interconnect region R.

The through holes 10x may be formed by wet etching, for example. Examples of the etching solution used in this process include hydrofluoric acid, strong alkali solution, and the like. If the through holes 10x were formed by drilling, there would be a risk that cracks may occur in the glass constituting the core layer 10. However, the use of wet etching enables the formation of the through holes 10x without causing cracks in the glass.

In the step illustrated in FIGS. 3B to 3D, a first laminate 51 including interconnect layers and insulating layers alternately laminated is formed on the first surface 10a of the core layer 10. Further, a second laminate 52 including interconnect layers and insulating layers alternately laminated is formed on the second surface 10b of the core layer 10. Specifically, as illustrated in FIG. 3B, an interconnect layer 12 is disposed in each interconnect region R on the first surface 10a of the core layer 10, and an interconnect layer 22 is disposed in each interconnect region R on the second surface of the core layer 10, with through interconnects 11 formed in the through holes 10x. For example, a seed layer (copper or the like) covering the first surface 10a, the second surface 10b of the core layer 10, and the inner wall surfaces of the through holes 10x is formed by an electroless plating method, a sputtering method, or the like, and an electroplating layer (copper or the like) is formed on the seed layer by an electroplating method using the seed layer as a current supply path. This arrangement fills the through holes 10x with the electrolytic plating layer formed on the seed layer, and forms a conductive layer as a laminate of the seed layer and the electrolytic plating layer on each of the first surface 10a and the second surface 10b of the core layer 10. Thereafter, the conductor layers are patterned into predetermined plan shapes by a subtractive method or the like to form the interconnect layers 12 and 22.

As illustrated in FIG. 3C, insulating layers 13 and 23 and interconnect layers 14 and 24 are formed. First, the insulating layer 13 covering the upper surface of the interconnect layer 12 is disposed in each interconnect region R and each cutting region D on the first surface 10a of the core layer 10. Specifically, for example, a semi-cured epoxy-based resin film or the like is laminated on the first surface 10a of the core layer 10 so as to cover the interconnect layer 12, and then cured to form the insulating layer 13. Alternatively, instead of laminating epoxy-based resin film or the like, epoxy-based resin or the like in liquid or paste form may be applied and then cured to form the insulating layer 13. The material and the thickness of the insulating layer 13 are as previously described. Similarly, the insulating layer 23 covering the lower surface of the interconnect layer 22 is disposed in each interconnect region R and each cutting region D on the second surface 10b of the core layer 10.

Next, via holes 13x are formed in the insulating layer 13 to penetrate the insulating layer 13 and expose the upper surface of the interconnect layer 12. Further, via holes 23x are formed in the insulating layer 23 to penetrate the insulating layer 23 and expose the lower surface of the interconnect layer 22. The via holes 13x and 23x may be formed by a laser processing method using, for example, a CO2 laser. After the via holes 13x and 23x are formed, desmearing treatment is preferably performed to remove resin residues adhering to the surfaces of the interconnect layers 12 and 22 exposed at the end of the via holes 13x and 23x.

The interconnect layer 14 is then formed on the first side of the insulating layer 13. The interconnect layer 14 includes via interconnects filling the via holes 13x and an interconnect pattern formed on the upper surface of the insulating layer 13. The interconnect layer 14 is electrically connected to the interconnect layer 12 exposed at the bottom of the via holes 13x. Similarly, the interconnect layer 24 is formed on the second side of the insulating layer 23. The interconnect layer 24 includes via interconnects filling the via holes 23x and an interconnect pattern formed on the lower surface of the insulating layer 23. The interconnect layer 24 is electrically connected to the interconnect layer 22 exposed at the end of the via holes 23x. The materials of the interconnect layers 14 and 24 and the thicknesses of the interconnect patterns may be substantially the same as those of the interconnect layer 12, for example. The interconnect layers 14 and 24 are formed, for example, by a semi-additive method.

As illustrated in FIG. 3D, insulating layers 15 and 25, interconnect layers 16 and 26, solder resist layers 17 and 27, and external connection terminals 18 are formed. First, the same steps as those of FIG. 3C are repeated to form the insulating layers 15 and 25 and the interconnect layers 16 and 26. Next, the solder resist layer 17 is formed on the upper surface of the insulating layer 15 so as to cover the interconnect layer 16. Further, the solder resist layer 27 is formed on the lower surface of the insulating layer 25 so as to cover the interconnect layer 26. The solder resist layer 17 may be formed, for example, by applying a photosensitive epoxy-based insulating resin in liquid or paste form to the upper surface of the insulating layer 15 so as to cover the interconnect layer 16 by screen printing, roll coating, spin coating, or the like. Alternatively, a photosensitive epoxy-based insulating resin film, for example, may be laminated on the upper surface of the insulating layer 15 so as to cover the interconnect layer 16. The method of forming the solder resist layer 27 is substantially the same as that of the solder resist layer 17. Thereafter, the solder resist layers 17 and 27 are exposed and developed. As a result, openings 17x are formed through the solder resist layer 17 to expose the interconnect layer 16. Also, openings 27x for exposing portions of the lower surface of the interconnect layer 26 are formed through the solder resist layer 27. According to need, the external connection terminals 18 may be provided on the interconnect layer 16 exposed in the openings 17x. The external connection terminals 18 are, for example, solder bumps formed by solder reflow or the like.

In the step illustrated in FIG. 4A, first grooves 51x, each straddling a corresponding cutting region D, are formed so as to penetrate the first laminate 51 and expose the first surface 10a of the core layer 10. The first grooves 51x are formed along the cutting regions D and throughout the cutting regions D. In each interconnect region R, the first surface 10a of the core layer 10 exposed in the first grooves 51x is a portion which becomes the first peripheral portion 10s after singulation. Further, second grooves 52x, each straddling a corresponding cutting region D, are formed so as to penetrate the second laminate 52 and expose the second surface 10b of the core layer 10. The second grooves 52x are formed along the cutting regions D and throughout the cutting regions D. In each interconnect region R, the second surface 10b of the core layer 10 exposed in the second grooves 52x is a portion that becomes the second peripheral portion 10t after singulation. The first grooves 51x and the second grooves 52x may be formed, for example, by irradiating the first laminate 51 and the second laminate 52 with a laser beam having an absorptive wavelength. In the case of irradiating the laser beam, the widths of the first grooves 51x and the second grooves 52x increase with the distance from the core layer 10, for example. The first grooves 51x and the second grooves 52x may be formed by using a cutting blade.

After the first grooves 51x and the second grooves 52x are formed, the first surface 10a of the core layer 10 exposed in the first grooves 51x is irradiated with a laser beam L along the cutting regions D. By condensing the laser beam inside the core layer 10, a modified layer serving as a starting point for division is formed inside the core layer 10 at the positions located under the cutting regions D. In this step, the core layer 10 is irradiated with the laser beam having a transmissive wavelength.

In the step illustrated in FIG. 4B, a first resin portion 41 is formed to cover both the first surface 10a of the core layer 10 exposed in the first grooves 51x and a portion of the inner surfaces of the first grooves 51x located adjacent to the first surface 10a of the core layer 10. Further, a second resin portion 42 is formed so as to cover both the second surface 10b of the core layer 10 exposed in the second grooves 52x and a portion of the inner surfaces of the second grooves 52x located adjacent to the second surface 10b of the core layer 10. For example, an uncured resin is applied into the first grooves 51x by potting and cured to effectively form the first resin portion 41. The second resin portion 42 may also be formed in substantially the same manner. The first resin portion 41 and the second resin portion 42 are thinnest at the same positions as the cutting regions D in plan view, and become thicker away from the cutting regions D in plan view.

The materials of the first resin portion 41 and the second resin portion 42 may be, for example, an insulating resin mainly composed of an epoxy-based resin or a polyimide-based resin. The first resin portion 41 and the second resin portion 42 preferably do not contain a filler. Alternatively, the content of the filler is preferably smaller than that of the resin of the insulating layers. This facilitates cutting of the first resin portion 41 and the second resin portion 42 when the first resin portion 41, the core layer 10, and the second resin portion 42 are cut along the cutting regions D in the step illustrated in FIG. 4C.

The thickness of the thinnest portion of the first resin portion 41 in the stacking direction of the first laminate 51 may be, for example, from 10 μm to 50 μm. The thickness of the thinnest portion of the second resin portion 42 in the stacking direction of the second laminate 52 may be, for example, from 10 μm to 50 μm. When the thicknesses of the thinnest portions of the first resin portion 41 and the second resin portion 42 are 10 μm or more, the first resin portion 41 effectively provides sufficient protection for the first peripheral portion 10s that is not covered with the first laminate 51, and the second resin portion 42 effectively provides sufficient protection for the second peripheral portion 10t that is not covered with the second laminate 52. Provision of the thinnest portions of the first resin portion 41 and the second resin portion 42 that are 50 μm or less in thickness effectively facilitates cutting of the first resin portion 41 and the second resin portion 42 when the first resin portion 41, the core layer 10, and the second resin portion 42 are cut along the cutting regions D in the step illustrated in FIG. 4C.

In the step illustrated in FIG. 4C, the first resin portion 41, the core layer 10, and the second resin portion 42 are cut along the cutting regions D illustrated in FIG. 4B to produce a plurality of singulated interconnect substrates 1. By cutting along the cutting regions D, the first grooves 51x are each divided, and the first resin portion 41 covers both the first peripheral portion 10s and portions of the side surfaces 51c of the first laminate 51 located adjacent to the first peripheral portion 10s in each interconnect substrate 1. The second grooves 52x are also each divided, and the second resin portion 42 covers both the second peripheral portion 10t and portions of the side surfaces 52c of the second laminate 52 located adjacent to the second peripheral portion 10t in each interconnect substrate 1.

The cutting may be performed, for example, by attaching the structure illustrated in FIG. 4B to an expansion tape and stretching the tape radially outward with respect to the structure. Stretching the tape causes forces to be applied to the modified portions of the core layer 10, the first resin portion 41, and the second resin portion 42 in the radially outward direction in which the tape expands. As a result, the core layer 10 is divided along the modified layer serving as the starting point of separation, and the first resin portion 41 and the second resin portion 42 are also divided in the proximity of the cutting regions D.

Instead of the method of using the expansion tape, for example, a roller or a rod-shaped pressing member may be used to apply a force around the cutting regions D to divide the first resin portion 41, the core layer 10, and the second resin portion 42.

As described above, the method of making the interconnect substrate 1 includes forming each first groove 51x that straddles a corresponding cutting region D, forming a modified layer in the core layer 10 by irradiating the first surface 10a of the core layer 10 exposed in the first groove 51x with a laser beam, and forming the first resin portion 41 in the first groove 51x. Further, each second groove 52x is formed so as to straddle a corresponding cutting region D, and the second resin portion 42 is formed in the second groove 52x. Then, the first resin portion 41, the core layer 10, and the second resin portion 42 are cut along the cutting regions D to produce a plurality of singulated interconnect substrates 1.

As a result, the first peripheral portion 10s of the first surface 10a of the core layer 10 is covered with the first resin portion 41 in the singulated interconnect substrate 1, which effectively reduces breakage such as chipping or cracking of the first peripheral portion 10s. Further, the second peripheral portion 10t of the second surface 10b of the core layer 10 is covered with the second resin portion 42 in the singulated interconnect substrate 1, which effectively reduces breakage such as chipping or cracking of the second peripheral portion 10t .

### Variation of First Embodiment

A variation of the first embodiment is directed to an example in which the upper surfaces of the resin portions are flat. In connection with the variation of the first embodiment, descriptions of the same components as those of the already described embodiment may be omitted.

FIG. 5 is a cross-sectional view illustrating an example of an interconnect substrate according to a variation of the first embodiment; and Referring to FIG. 5, an interconnect substrate 1A differs from the interconnect substrate 1 (see FIG. 1B) in that the first resin portion 41 and the second resin portion 42 are replaced with a first resin portion 45 and a second resin portion 46, respectively.

Like the first resin portion 41, the first resin portion 45 covers the first peripheral portion 10s and portions of the side surfaces 51c of the first laminate 51 located adjacent to the first peripheral portion 10s. The upper surface of the first resin portion 45 is flat and, for example, parallel to the first surface 10a of the core layer 10. The thickness of the first resin portion 45 in the stacking direction of the first laminate 51 is constant and may be, for example, from 10 μm to 100 μm.

Like the second resin portion 42, the second resin portion 46 covers the second peripheral portion 10t and portions of the side surfaces 52c of the second laminate 52 located adjacent to the second peripheral portion 10t . The lower surface of the second resin portion 46 is flat and, for example, parallel to the second surface 10b of the core layer 10. The thickness of the second resin portion 46 in the stacking direction of the second laminate 52 is constant and may be, for example, from 10 μm to 100 μm.

The material of the first resin portion 45 and the second resin portion 46 may be, for example, an insulating resin mainly composed of an epoxy-based resin or a polyimide-based resin. In the present application, the term “parallel” means that a tolerance of ±10 degrees is allowed for parallel alignment. The constant thickness means that the thickness of the thickest portion is not more than +10% above the thickness of the thinnest portion.

To form the first resin portion 45 and the second resin portion 46, for example, in the step illustrated in FIG. 4B of the first embodiment, strips of a semi-cured insulating resin film with an appropriate size are disposed in the first grooves 51x and the second grooves 52x and cured. Thereafter, substantially the same step as that illustrated in FIG. 4C of the first embodiment may be performed.

As described above, the upper surface of the first resin portion 45 and the lower surface of the second resin portion 46 may be flat. In this case also, since the first peripheral portion 10s of the first surface 10a of the core layer 10 is covered with the first resin portion 45, the occurrence of breakage such as chipping or cracking in the first peripheral portion 10s is effectively reduced. Further, since the second peripheral portion 10t of the second surface 10b of the core layer 10 is covered with the second resin portion 46, the occurrence of breakage such as chipping or cracking in the second peripheral portion 10t is effectively reduced.

### Second Embodiment

The second embodiment is directed to an example of a semiconductor device in which a semiconductor chip is mounted on the interconnect substrate according to the first embodiment. It may be noted that, in connection with the second embodiment, descriptions of the same components as those in the already described embodiment may be omitted.

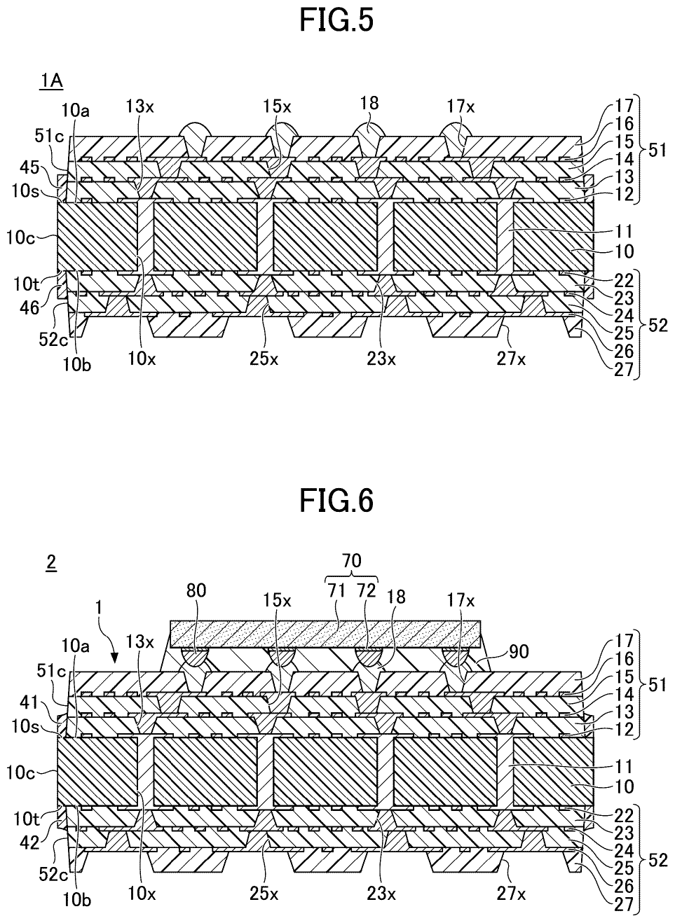

FIG. 6 is a cross-sectional view illustrating an example of a semiconductor device according to the second embodiment. Referring to FIG. 6, a semiconductor device 2 includes the interconnect substrate 1 illustrated in FIGS. 1A and 1B, a semiconductor chip 70, bumps 80, and an underfill resin 90.

The semiconductor chip 70 includes a chip 71 and electrodes 72. The chip 71 is configured such that a semiconductor integrated circuit (not illustrated) or the like is formed on a thin semiconductor substrate (not illustrated) made of, for example, silicon. The electrodes 72 electrically connected to the semiconductor integrated circuit are formed on the semiconductor substrate (not illustrated).

The bumps 80 are formed on the electrodes 72 of the semiconductor chip 70, and electrically connects the electrodes 72 and the external connection terminals 18 of the interconnect substrate 1. The electrodes 72 may be formed of, for example, copper. The bumps 80 may be, for example, solder bumps. The material of the solder bumps may be, for example, an alloy containing Pb, an alloy of Sn and Cu, an alloy of Sn and Ag, an alloy of Sn, Ag and Cu, or the like. The underfill resin 90 fills a gap between the semiconductor chip 70 and the upper surface of the solder resist layer 17 of the interconnect substrate 1.

In this manner, the fabrication of a semiconductor device is effectively achieved by mounting the semiconductor chip on the interconnect substrate according to the first embodiment. The interconnect substrate 1A may be used instead of the interconnect substrate 1.

According to at least one embodiment, an interconnect substrate having a core layer made of glass is provided in which the breakage of the peripheral portion of the core layer is reduced.

Although the preferred embodiments have been described in detail, the present invention is not limited to these embodiments, and various modifications and substitutions may be made to the above-described embodiments without departing from the scope of the appended claims.

For example, the above-described embodiments are directed to the interconnect substrate that has the first laminate on the first surface of the core layer made of glass and the second laminate on the second surface. However, the present invention may be applied to an interconnect substrate having the first laminate on the first surface of the core layer made of glass and not having the second laminate on the second surface, while providing substantially the same advantageous effects. In the case where the interconnect substrate does not have the second laminate, the through holes may not be provided in the core layer.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

The present disclosures non-exhaustively contain the subject matter set out in the following clauses.

[Clause 1] A method of making an interconnect substrate, comprising:

providing a glass core layer having a plurality of interconnect regions for singulation into interconnect substrates and cutting regions along which cuts are to be made for the singulation;
forming a first laminate including one or more interconnect layers and one or more insulating layers on one surface of the core layer;
forming first grooves penetrating the first laminate and exposing the one surface of the core layer, each of the first grooves straddling a corresponding one of the cutting regions;
forming a modified layer inside the core layer by irradiating the one surface of the core layer exposed in the first grooves with a laser beam along the cutting regions;
forming a first resin portion covering the one surface of the core layer exposed in the first grooves and inner surfaces of the first grooves; and
cutting the first resin portion and the core layer along the cutting regions to produce the plurality of interconnect substrates.

[Clause 2] The method according to clause 1, further comprising:
forming a second laminate including one or more interconnect layers and one or more insulating layers on another surface of the core layer;
forming second grooves penetrating the second laminate and exposing the another surface of the core layer, each of the second grooves straddling a corresponding one of the cutting regions; and
forming a second resin portion covering the another surface of the core layer exposed in the second grooves and inner surfaces of the second grooves, wherein the cutting the first resin portion and the core layer cuts the second resin portion along the cutting regions in addition to the first resin portion and the core layer to produce the plurality of interconnect substrates.

What is claimed is:

1. An interconnect substrate comprising:
a core layer made of glass having one surface and another surface;
a first laminate including one or more interconnect layers and one or more insulating layers disposed on the one surface of the core layer; and
a first resin portion,
wherein a first peripheral portion of the one surface of the core layer is not covered with the first laminate, and
wherein the first resin portion covers the first peripheral portion and a side surface of the first laminate.

2. The interconnect substrate according to claim 1, wherein a height of an upper surface of the first resin portion from the one surface of the core layer decreases with distance from the side surface of the first laminate toward a side surface of the core layer.

3. The interconnect substrate according to claim 1, wherein the first resin portion is free of a filler.

4. The interconnect substrate according to claim 1, wherein an upper surface of the first resin portion is parallel to the one surface of the core layer.

5. The interconnect substrate according to claim 1, further comprising:
a second laminate including one or more interconnect layers and one or more insulating layers disposed on the another surface of the core layer; and
a second resin portion,
wherein a second peripheral portion of the another surface of the core layer is not covered with the second laminate, and
wherein the second resin portion covers the second peripheral portion and a side surface of the second laminate.

6. The interconnect substrate according to claim 5, wherein a vertical distance of a lower surface of the second resin portion from the another surface of the core layer decreases with distance from the side surface of the second laminate toward a side surface of the core layer.

7. The interconnect substrate according to claim 5, wherein the second resin portion is free of a filler.

8. The interconnect substrate according to claim 5, wherein a lower surface of the second resin portion is parallel to the another surface of the core layer.
